(19) United States
(12) Patent Application Publication
(10) Pub. No.: US 2026/0114298 A1
(43) Pub. Date: Apr. 23, 2026

(54) ELECTRONIC DEVICE HAVING A SUBSTRATE EMPLOYING REDUCED AREA, ADDED METAL PAD(S) TO METAL INTERCONNECT(S) TO REDUCE AIR VOIDS IN SOLDER JOINTS

(71) Applicant: QUALCOMM Incorporated, San Diego, CA (US)

(72) Inventors: Jay Scott Salmon, San Diego, CA (US); Anirudh Bhat, San Diego, CA (US)

(21) Appl. No.: 18/919,934

(22) Filed: Oct. 18, 2024

(51) Int. Cl. H01L 23/00; H01L 23/538; H01L 25/065

(52) U.S. Cl. CPC H10W 70/611; H10W 70/685; H10W 90/00; H10W 72/01257; H10W 72/01357; H10W 72/072; H10W 72/073; H10W 72/07311; H10W 72/241; H10W 72/856; H10W 72/926; H10W 90/724; H10W 90/734

(57) ABSTRACT

An electronic device having a substrate employing reduced area, added metal pad(s) to a metal interconnect(s) to reduce air voids in a solder joint and related fabrication methods are disclosed. The electronic device includes a die that has die interconnects coupled to a first metal pad(s) of a respective metal interconnect(s) of a metallization layer of the substrate through a second, additional metal pad(s). To facilitate a reduction in air voids in the solder joint between the die and the first metal pad(s) and consequently the amount of solder between the first metal pad and the die, the second, additional metal pad(s) having a reduced cross-sectional area from the first metal pad(s) is above and adjacent to the first metal pad(s). A solder joint(s) is employed to couple the second, additional metal pad(s) to a die interconnect(s) of the die to couple the die to the substrate.

### TECHNICAL FIELD

The field of the disclosure relates to integrated circuit (IC) packages, and more particularly to design and manufacture of a substrate within an IC package.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The die(s) is electrically interfaced to metal interconnects (e.g., metal traces) exposed in a top layer of the package substrate. The package substrate also includes one or more metallization layers that include metal interconnects (e.g., metal traces, metal lines) with vertical interconnect accesses (vias) coupling the metal interconnects together between adjacent metallization layers to provide electrical interfaces between the dies. The package substrate also includes a bottom, outer metallization layer that includes metal interconnects coupled to external metal interconnects (e.g., ball grid array (BGA) interconnects, land grid array (LGA)) to provide an external interface between the dies in the IC package. The external metal interconnects can also be coupled (e.g., soldered) to metal pads in a printed circuit board (PCB) to attach the package to the PCB and interface its die(s) with the circuitry of the PCB. The die(s) may be mounted to the top layer of the package substrate through die interconnects by a screen-printing process which involves multiple print screen stencils. Each print screen stencil has openings or apertures sized according to the size(s) of the metal pads that the respective print screen stencil is designed to cover. Solder paste is squeezed through each print screen stencil in a separate process step onto the respective metal pads in the PCB sized for the specific print screen stencil. Other dies may also be mounted, utilizing die interconnects, to the bottom, outer metallization layer that includes metal interconnects between BGA interconnects.

### SUMMARY

Aspects disclosed in the detailed description include an electronic device having a substrate employing a reduced area, added metal pad(s) to a metal interconnect(s) to reduce air voids in a solder joint. The electronic device includes a die that has die interconnects coupled to a first metal pad(s) of respective metal interconnects of a metallization layer of the substrate (e.g., a package substrate) through second, additional metal pads. As an example, to facilitate a reduction in air voids in the solder between the die and the first metal pad(s) and consequently the amount of solder between the first metal pad and the die, the second, additional metal pad(s) having a reduced cross-sectional area from the first metal pad(s) is adjacent to the first metal pad(s). A solder joint(s) is employed to couple the second, additional metal pad(s) to a die interconnect(s) of the die to couple the die to the substrate. In this manner, as an example, the second, additional metal pad(s) consumes volume in space that would otherwise be consumed by solder reducing the air voids in the solder joint.

Air voids in a solder joint negatively impact thermal dissipation from the die through the solder joint and may also impact the structural integrity of the solder joint. Air voids in the solder joint may more frequently occur when there are metal pads that have different cross-sectional areas and a single print screen stencil is used during fabrication to reduce fabrication costs. In that situation, when solder paste is applied on the single print screen stencil, it is difficult to balance the amount of solder paste needed to avoid shorting adjacent metal pads with a smaller relative cross-sectional area while, at the same time, applying enough solder paste to form a structural solder joint on a metal pad with a larger relative cross-sectional area. Utilizing a second, additional metal pad(s) adjacent to a metal pad(s) with a larger relative cross-sectional area to consume volume that would otherwise be consumed by solder paste advantageously allows a selected volume of solder paste that can be used in a single print screen stencil fabrication which will balance avoiding electrical shorts between adjacent metal pads having a small relative cross-sectional area compared to other metal pads that have a larger relative cross-sectional area while reducing, if not eliminating, air voids in solder joints formed on the other metal pad(s).

In this regard in one aspect, an electronic device is disclosed. The electronic device comprises an integrated circuit (IC) package. The IC package comprises a die comprising a plurality of die interconnects and a substrate comprising an outer metallization layer extending in a first direction. The outer metallization layer comprises a first metal pad having a first surface, the first metal pad having a first cross-sectional area extending in the first direction. The outer metallization layer also comprises a second metal pad above and adjacent to the first surface, the second metal pad having a second cross-sectional area extending in the first direction, the second cross-sectional area is less than the first cross-sectional area. The outer metallization layer comprises a third metal pad having a third surface, the third metal pad having a third cross-sectional area extending in the first direction, the third cross-sectional area is less than the first cross-sectional area. The IC package also comprises a first solder joint coupled to the second metal pad and a first die interconnect of the plurality of die interconnects and a second solder joint coupled to the third metal pad and a second die interconnect of the plurality of die interconnects.

In another aspect, a method for fabricating an electronic device is disclosed. The method comprises forming a die comprising a plurality of die interconnects. The method also comprises forming a substrate, the substrate comprising an outer metallization layer extending in a first direction. The outer metallization layer comprises a first metal pad having a first surface, the first metal pad having a first cross-sectional area extending in the first direction. The outer metallization layer also comprises a second metal pad above and adjacent to the first surface, the second metal pad having a second cross-sectional area extending in the first direction, the second cross-sectional area is less than the first cross-sectional area. The outer metallization layer also comprises a third metal pad having a third surface, the third metal pad having a third cross-sectional area extending in the first direction, the third cross-sectional area is less than the first cross-sectional area. The method also comprises forming a first solder joint and a second solder joint, the first solder joint coupled to the second metal pad and a first die interconnect of the plurality of die interconnects and the second solder joint coupled to the third metal pad and a second die interconnect of the plurality of die interconnects.

### BRIEF DESCRIPTION OF THE DRAWINGS

FIG. 1A is a side view of an exemplary three-dimensional (3D) integrated circuit (IC) (3DIC) package that includes a substrate employing a reduced area, added metal pad(s) to a metal interconnect(s) to reduce air voids in a solder joint;

FIG. 1B is a side view of an exemplary electronic device including the 3DIC package as described in FIG. 1A and deployed on a printed circuit board (PCB), wherein the PCB is a substrate employing a reduced area, added metal pad(s) to a metal interconnect(s) to reduce air voids in a solder joint;

FIG. 2 is close-up view of the exemplary substrate shown in FIG. 1A between cut lines A1 and A2, employing a reduced area, added metal pad(s) to a metal interconnect(s) to reduce air voids in a solder joint;

FIG. 3A is a perspective view of a substrate embodiment of the exemplary substrate shown in FIG. 2 in the negative Z-direction from cut line B1 in FIG. 2A;

FIG. 3B is a perspective view of another substrate embodiment of the exemplary substrate shown in FIG. 2 in the negative Z-direction from cut line B1 in FIG. 2A;

FIG. 4 is a flowchart illustrating an exemplary fabrication process of fabricating an IC package such as the IC package described in FIGS. 1A-1B, 2, and FIGS. 3A-3B, wherein the IC package includes a substrate employing a reduced area, added metal pad(s) to a metal interconnect(s) to reduce air voids in a solder joint(s), including, but not limited to, the solder joints in FIGS. 1A-1B;

FIGS. 5A-5B is a flowchart illustrating another exemplary fabrication process of fabricating an IC package utilizing a substrate such as the IC package described in FIGS. 1A-1B, 2, and FIGS. 3A-3B, wherein the substrate employs a reduced area, added metal pad(s) to a metal interconnect(s) to reduce air voids in a solder joint(s), including, but not limited to, the solder joints in FIGS. 1A-1B;

FIGS. 6A-6D are exemplary fabrication stages during fabrication of the IC package according to the fabrication process in FIGS. 5A-5B;

FIG. 7 is a flowchart illustrating an exemplary assembly process of assembling an electronic device such as the electronic device having a PCB in FIG. 1B and utilizing the IC package fabricated according to the fabrication process in FIGS. 5A-5B, wherein the PCB employs a reduced area, added metal pad(s) to a metal interconnect(s) to reduce air voids in a solder joint(s) including, but not limited to, the solder joints in FIGS. 1A-1B;

FIGS. 8A-8C are exemplary assembly stages during assembly of the electronic device according to the assembly process in FIG. 7;

FIG. 9 is a block diagram of an exemplary processor-based system that can include components deployed in an electronic device, wherein the electronic device includes a substrate(s) employing a reduced area, added metal pad(s) to a metal interconnect(s) to reduce air voids in a solder joint, including, but not limited to, the solder joints in FIGS. 1A-1B and according to the exemplary fabrication processes in FIGS. 4 and 5A-5C; and

FIG. 10 is a block diagram of an exemplary wireless communications device that includes radio-frequency (RF) components formed from one or more electronic devices, wherein any of the electronic devices includes an IC package wherein the IC package includes a substrate(s) employing a reduced area, added metal pad(s) to a metal interconnect(s) to reduce air voids in solder joint(s), including, but not limited to, the solder joints in FIGS. 1A-1B and according to the exemplary fabrication processes in FIGS. 4 and 5A-5C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

It should be understood that the terms “first,” “second,” “third,” etc., where used herein, are relative terms and are not meant to limit or imply a strict orientation. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. For example, if a particular object that is discussed as at “top,” or “upper” or “above” another object, and such particular object is flipped 180 degrees, then such particular object would then be oriented as at “bottom,” or “lower” or “below” such other object.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Aspects disclosed in the detailed description include an electronic device having a substrate employing a reduced area, added metal pad(s) to a metal interconnect(s) to reduce air voids in a solder joint. The electronic device includes a die that has die interconnects coupled to a first metal pad(s) of respective metal interconnects of a metallization layer of the substrate (e.g., a package substrate) through second, additional metal pads. As an example, to facilitate a reduction in air voids in the solder between the die and the first metal pad(s) and consequently the amount of solder between the first metal pad and the die, the second, additional metal pad(s) having a reduced cross-sectional area from the first metal pad(s) is adjacent to the first metal pad(s). A solder joint(s) is employed to couple the second, additional metal pad(s) to a die interconnect(s) of the die to couple the die to the substrate. In this manner, as an example, the second, additional metal pad(s) consumes volume in space that would otherwise be consumed by solder reducing the air voids in the solder joint.

Air voids in a solder joint negatively impact thermal dissipation from the die through the solder joint and may also impact the structural integrity of the solder joint. Air voids in the solder joint may more frequently occur when there are metal pads that have different cross-sectional areas and a single print screen stencil is used during fabrication to reduce fabrication costs. In that situation, when solder paste is applied on the single print screen stencil, it is difficult to balance the amount of solder paste needed to avoid shorting adjacent metal pads with a smaller relative cross-sectional area while, at the same time, applying enough solder paste to form a structural solder joint on a metal pad with a larger relative cross-sectional area. Utilizing a second, additional metal pad(s) adjacent to a metal pad(s) with a larger relative cross-sectional area to consume volume that would otherwise be consumed by solder paste advantageously allows a selected volume of solder paste that can be used in a single print screen stencil process which will balance avoiding electrical shorts between adjacent metal pads having a small relative cross-sectional area compared to other metal pads that have a larger relative cross-sectional area while reducing, if not eliminating, air voids in solder joints formed on the other metal pad(s).

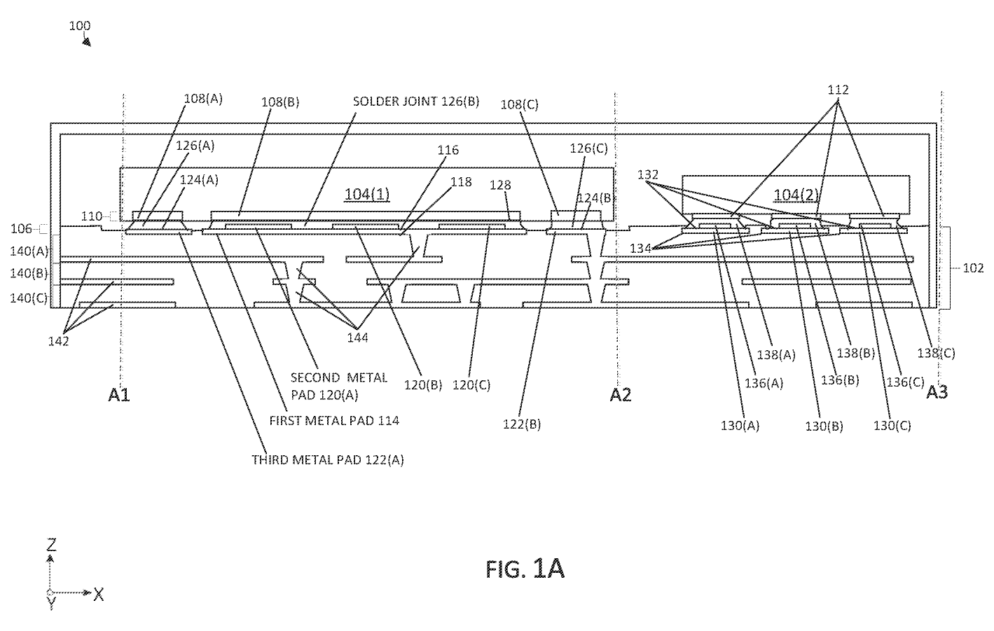

In this regard, FIG. 1A is a side view of an exemplary IC package 100, which in this example is a three-dimensional (3D) IC (3DIC) package 100. The IC package 100 includes a substrate 102 extending in a first, horizontal direction (X-, Y-axes direction). In this example, the IC package 100 includes first and second dies 104(1), 104(2) that are coupled to the substrate 102 in the second, vertical direction (Z-axis direction). The substrate 102 commonly routes signals, power, and ground between the first and second dies 104(1), 104(2), and between the first and second dies 104(1), 104(2) to a printed circuit board (PCB) (not shown).

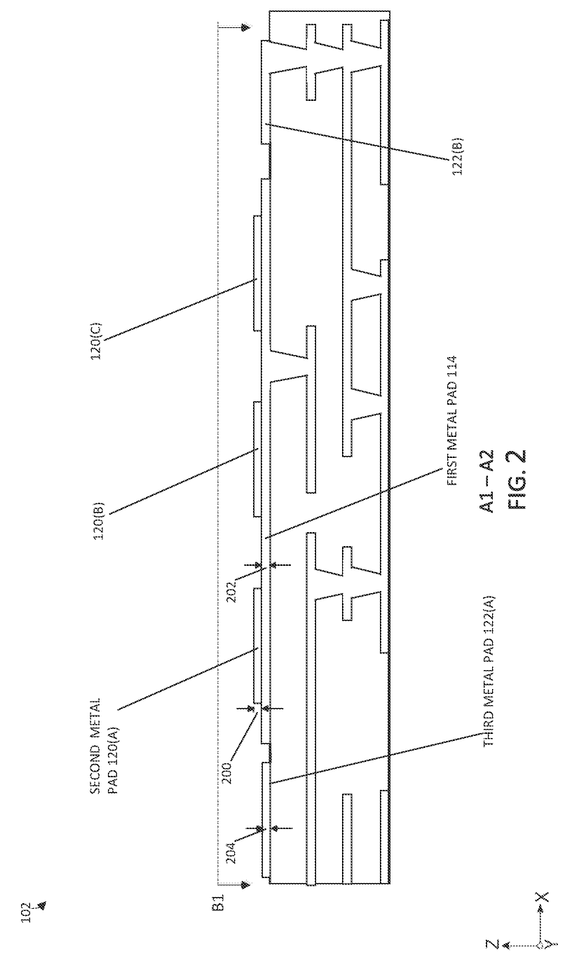

In this example, the substrate 102 includes a first, outer metallization layer 106 extending in the first, horizontal direction (X-, Y-axes direction). The first, outer metallization layer 106 provides an electrical interface for signal and power/ground routing to the first die 104(1) and the second die 104(2). The first die 104(1) includes die interconnects 108(A)-108(C) (e.g., embedded metal pads) in a metallization layer 110. The second die 104(2) includes die interconnects 112 (e.g., external metal pads or pillars). The outer metallization layer 106 includes a first metal pad 114. The first metal pad 114 includes a first surface 116 and a second surface 118 opposite the first surface 116 in the second direction (Z-axis direction) orthogonal to the first direction. The first metal pad 114 has a first cross-sectional area extending in the first direction on the first surface 116. The outer metallization layer 106 includes second metal pads 120(A)-120(C). The term “second metal pad” is also referred to as a micro metal pad because it is above and adjacent to a lower metal pad in a metallization layer. The second metal pads 120(A)-120(C) are above and adjacent to the first surface 116 of the first metal pad 114 and each have a second cross-sectional area extending in the first direction. Each of the second cross-sectional areas is less than the first cross-sectional area of the first metal pad 114. The outer metallization layer 106 includes third metal pads 122(A)-122(B). The third metal pads 122(A)-122(B) are in the same plane as the first metal pad 114 and couple the die interconnects 108(A)-108(C) to the substrate 102. The third metal pads 122(A)-122(B) include a respective surface 124(A)-124(B) wherein the cross-sectional area of the respective surface 124(A)-124(B) is less than the first cross-sectional area. Further discussion of the cross-sectional area will be found in connection with FIGS. 3A-3B.

Solder joints 126(A), 126(C) couple the third metal pads 122(A), 122(B) to die interconnects 108(A), 108(C), respectively. Solder joint 126(B) couples the first metal pad 114 to the die interconnect 108(B). The die interconnect 108(B) may be a ground plane and is adjacent to a bottom surface 128 of the die 104(1). The die interconnect 108(B) may be a primary thermal dissipation path of heat through the bottom surface 128. The die interconnects 108(A), 108(C) may be signal interconnects and are electrically coupled to the third metal pads 122(A), 122(B), respectively, to carry electrical signals. In this embodiment, the third metal pads 122(A), 122(B) may also be referred to as signal pads.

The second die 104(2) includes first metal pads 130(A)-130(C). The first metal pads 130(A)-130(C) include a first surface 132 and a second surface 134 opposite the first surface 132 in the second direction orthogonal to the first direction. Each of the first metal pads 130(A)-130(C) has a first cross-sectional area extending in the first direction on the respective first surface 132. The outer metallization layer 106 includes second metal pads 136(A)-136(C). The second metal pads 136(A)-136(C) are above and adjacent to the respective first surface 132 of the first metal pads 130(A)-130(C) and each have a second cross-sectional area extending in the first direction. Each of the respective second cross-sectional areas of the second metal pads 136(A)-136(C) is less than the first cross-sectional areas of each of the first metal pads 130(A)-130(C).

Solder joints 138(A)-138(C) couple the first metal pads 130(A)-130(C) and the second metal pads 132(A)-132(C) to the die interconnects 112, respectively. The second metal pads 132(A)-132(C) consume volume so that less solder can be used in the solder joint which reduces or eliminates air voids in the solder joints 138(A)-138(C).

The substrate 102 includes metallization layers 140(A)-140(C), each including metal interconnects, such as metal interconnects 142 (e.g., traces, lines, tracks) and vias, such as vias 144, coupling one metallization layer to an adjacent metallization layer. Metallization layer 140(C) includes substate interconnects to couple the substrate 102 to a PCB which will be discussed in FIG. 1B.

FIG. 1B is a side view of an exemplary electronic device 145 including the 3DIC package 100 as described in FIG. 1A and assembled on a PCB 146, wherein the PCB 146 is a substrate employing a reduced area, added metal pad(s) to a metal interconnect(s) to reduce air voids in a solder joint coupling the 3DIC package 100 to the PCB 146. The electronic device 145 includes a third die 104(3).

In this example, the PCB 146 includes a first, outer metallization layer 147 extending in the first, horizontal direction. The first, outer metallization layer 147 provides an electrical interface for signal and power/ground routing between the 3DIC package 100 and the third die 104(3). The 3DIC package 100 includes package interconnects 148(A)-148(D) (e.g., embedded metal pads) in metallization layer 140(C). The third die 104(3) includes die interconnects 150 (e.g., external metal pads or pillars). The outer metallization layer 147 includes first metal pads 152(A)-152(B). The first metal pads 152(A)-152(B) include first surfaces 154(A)-154(B) and second surfaces 156(A)-156(B) opposite the first surfaces 154(A)-154(B), respectively, in the second direction orthogonal to the first direction. The first metal pads 152(A)-152(B) have a first cross-sectional area extending in the first direction on the respective first surface 154(A)-154(B). The outer metallization layer 147 includes second metal pads 158(A)-158(D). The second metal pads 158(A)-158(B) are adjacent to the first surface 154(A) of the first metal pad 152(A) and each have a second cross-sectional area extending in the first direction. Each of the second cross-sectional areas of the second metal pads 158(A)-158(B) is less than the first cross-sectional area of the first metal pad 152(A). The second metal pads 158(C)-158(D) are adjacent to the first surface 154(B) of the first metal pad 152(B) and each have a second cross-sectional area extending in the first direction. Each of the second cross-sectional areas of the second metal pads 158(C)-158(D) is less than the first cross-sectional area of the first metal pad 152(B).

The outer metallization layer 147 includes third metal pads 160(A)-160(B). The third metal pads 160(A)-160(B) include a respective surface 162(A)-162(B) wherein the cross-sectional area of the respective surface 162(A)-162(B) is less than the first cross-sectional area of the respective first surface 154(A)-154(B).

The electronic device 145 includes solder joints 164(A)-164(D) to couple the dies 104(1),104(2) to the PCB 146. Solder joints 164(A), 164(D) couple the third metal pads 160(A), 160(B) to the package interconnects 148(A), 148(D), respectively. Solder joint 164(B) couples the second metal pads 158(A)-158(B) to the package interconnect 148(B). Solder joint 164(C) couples the second metal pads 158(C)-158(D) to the package interconnect 148(C).

The outer metallization layer 147 includes first metal pads 166(A)-166(C). The first metal pads 166(A)-166(C) include first surfaces 168(A)-168(C) and second surfaces 170(A)-170(C) opposite the first surfaces 168(A)-168(C), respectively, in the second direction orthogonal to the first direction. The first metal pads 166(A)-166(C) have first cross-sectional areas extending in the first direction on the respective first surface 168(A)-168(C). The outer metallization layer 147 includes second metal pads 172(A)-172(C). The second metal pads 172(A)-172(C) are adjacent to the first surfaces 168(A)-168(C) of first metal pads 166(A)-166(C), respectively, and each have a second cross-sectional area extending in the first direction. Each of the second cross-sectional areas of the second metal pads 172(A)-172(C) is less than the first cross-sectional area of the respective first metal pad 166(A)-166(C).

The electronic device 145 includes solder joints 174(A)-174(C). The solder joints 174(A)-174(C) couple the first metal pads 166(A)-166(C) and the second metal pads 172(A)-172(C) to the die interconnects 150, respectively. The second metal pads 172(A)-172(C) consume volume conventionally occupied by air voids in a solder joint which reduces or eliminates air voids in the solder joints 174(A)-174(C).

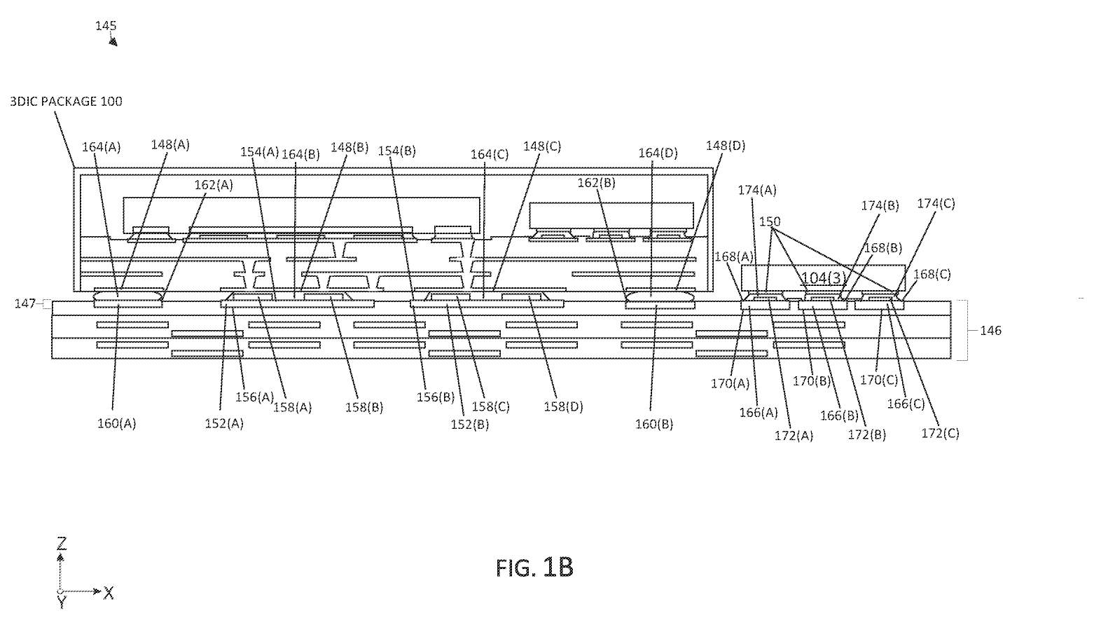

FIG. 2 is close-up view of the exemplary substrate 102 shown in FIG. 1A between cut lines A1 and A2, employing a reduced area, added metal pad(s) to a metal interconnect(s) to reduce air voids in a solder joint prior to screen printing solder paste onto the substrate 102. The height 200 of the second metal pads 120(A)-120(C) is generally equal to the height 202 of the first metal pad 114 and the height 204 of the third metal pad 122(A)-122(B). For a given height of the metal pads, the cross-sectional area of the metal pads is the controlling factor in determining the volume of solder displacement and is used herein as a proxy to volume.

FIG. 3A is a perspective view of a substrate 300 embodiment of the exemplary substrate 102 shown in FIG. 2 in the negative Z-direction from cut line B1 in FIG. 2. The substrate 300 includes a first metal pad 302 similar to the first metal pads described in FIGS. 1A-1B. The substrate 300 also includes ten second metal pads 304 similar to the second metal pads described in FIGS. 1A-1B. The ten second metal pads 304 are distributed equally in the first, horizontal direction (X-, Y-axes direction) within a perimeter 306 of the first metal pad 302. The first metal pad 302, second metal pad 304, and third metal pad 308 are within the periphery 309 of die 104(1). Preferably, the distance between any two adjacent second metal pads 304 or a second metal pad 304 adjacent to the perimeter 306 is a distance, d, in the X- or Y-axis direction. The substrate 300 also includes twenty-two third metal pads 308 similar to the third metal pads described in FIGS. 1A-1B. The twenty-two third metal pads 308 are distributed around the perimeter 306 of the first metal pad 302.

The first metal pad 302 has a length (l₁) equal to 2.5 micrometers (µm), a width (w₁) equal to 5 µm, and a first cross-sectional area (l₁ * w₁) equal to 12.5 micrometers² (µm²). Each second metal pad 304 has a length (l₂) equal to 0.61 µm, a width (w₂) equal to .0.61 µm, a cross-sectional area (l₂ * w₂) equal to 0.372 µm², and a total second cross-sectional area equal to (10 * 0.372) 3.72 µm². Each third metal pad 308 has a length (l₃) equal to 0.61 µm, a width (w₃) equal to .0.61 µm, and a cross-sectional area (l₃ * w₃) equal to 0.372 µm². In order for the second metal pads 304 to displace enough volume of solder paste, for a given height in the Z-axis direction, to both remove voids in solder while avoiding shorts created in a solder joint between third metal pads 308, the total second cross-sectional area of the second metal pads 304 is preferably at least thirty percent (30%) of the first cross-sectional area of the first metal pad 302. Doing so will allow solder joints coupling the first and second metal pads 302, 304 to die interconnects and the solder joints coupling the third metal pads 308 to other die interconnects to be fabricated with a single solder paste stencil.

FIG. 3B is a perspective view of another substrate 310 embodiment of the exemplary substrate 102 shown in FIG. 2 in the negative Z-direction from cut line B1 in FIG. 2. Common elements between the substrate 310 in FIG. 3B and the substrate 300 in FIG. 3A are shown with common element numbers. The substrate 310 includes twenty-two fourth metal pads 312 adjacent to the top surface of respective third metal pads 308. Each fourth metal pad 312 is adjacent in a second direction to each of the top surfaces of a respective third metal pad 308. Each of the plurality of fourth pads has a fourth cross-sectional area extending in the first direction, the fourth cross-sectional area being less than the cross-sectional area of the respective third metal pad 308. The substrate 310 also includes pads 314 within the periphery 316 of die 104(2) and suited to receive the die 104(2). The twenty-two four metal pads 312 are utilized in the substrate 310 because the size of pad 308 is much greater than the size of pads 314.

Please note that FIGS. 3A-3B illustrate the metal pads as squares. However, depending on fabrication tooling, these cross-sectional areas may be any shape including circles, rectangles, quadrangles, ovals, and the like. Also, please note the number of metal pads are shown for simplicity and can vary depending on the complexity of a corresponding die or package to which the respective pads will be coupled.

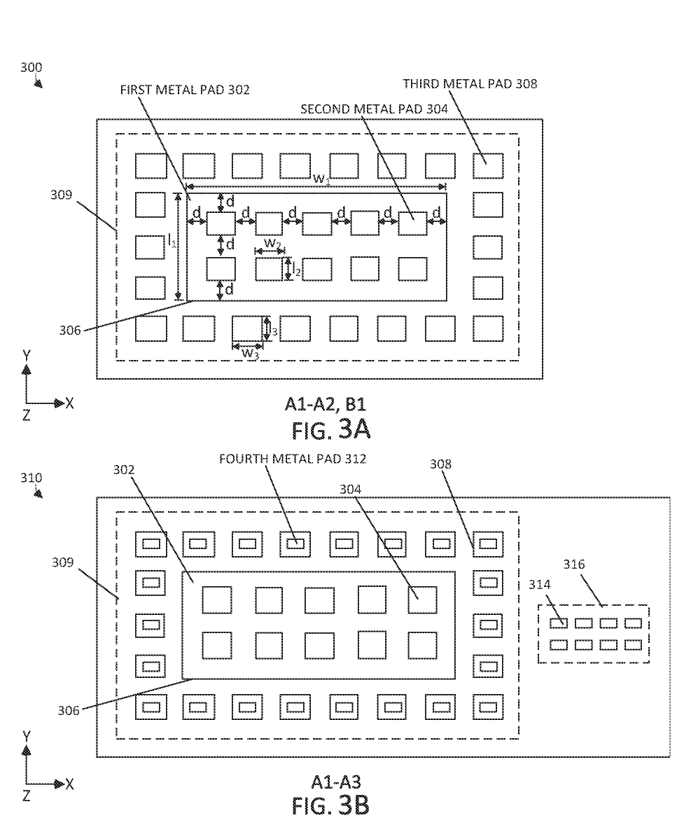

An IC package or electronic device employing an added metal pad(s) to a metal interconnect(s) in a substrate to reduce air voids in a solder joint, including, but not limited to, the IC package 100 in FIG. 1A or the electronic device in FIG. 1B can be fabricated by different fabrication processes. FIG. 4 is a flowchart illustrating an exemplary fabrication process of fabricating an IC package such as the IC package described in FIGS. 1A-1B, 2, and FIGS. 3A-3B, wherein the IC package includes a substrate employing an added metal pad(s) to a metal interconnect(s) to reduce air voids in a solder joint, including, but not limited to, the solder joints in FIGS. 1A-1B.

In this regard, a first exemplary step in the fabrication process 400 of FIG. 4 can include forming a die 104(1)-104(2) comprising a plurality of die interconnects 108(A)-108(C), 112 (block 402 in FIG. 4). A next step in the fabrication process 400 can include forming a substrate 102, 145, the substrate 102, 145 comprising an outer metallization layer 106, 147 extending in a first direction (block 404 in FIG. 4). The outer metallization layer 106, 147 comprises a first metal pad 114, 302 having a first surface 116, the first metal pad 114, 302 having a first cross-sectional area, l₁ x w₁, extending in the first direction and a second metal pad 120(A)-120(C), 304 above and adjacent to the first surface 116. The second metal pad 120(A)-120(C), 304 has a second cross-sectional area, l₂ x w₂, extending in the first direction wherein the second cross-sectional area, l₂ x w₂, is less than the first cross-sectional area, l₁ x w₁. The outer metallization layer 106, 147 also comprises a third metal pad 122(A)-122(B), 308 having a third surface 124(A). The third metal pad 122(A)-122(B), 308 has a third cross-sectional area, l₃ x w₃, extending in the first direction wherein the third cross-sectional area, l₃ x w₃, is less than the first cross-sectional area, l₁ x w₁. A next step in the fabrication process 400 can include forming a first solder joint 126(B) and a second solder joint 126(A), 126(C), the first solder joint 126(B) coupled to the second metal pad 120(A)-120(C), 304 and a first die interconnect 108(B) of the plurality of die interconnects 108(A)-108(C) and the second solder joint 126(A), 126(C) coupled to the third metal pad 122(A)-122(B), 308 and a second die interconnect 108(A), 108(C) of the plurality of die interconnects 108(A)-108(C) (block 406 in FIG. 4).

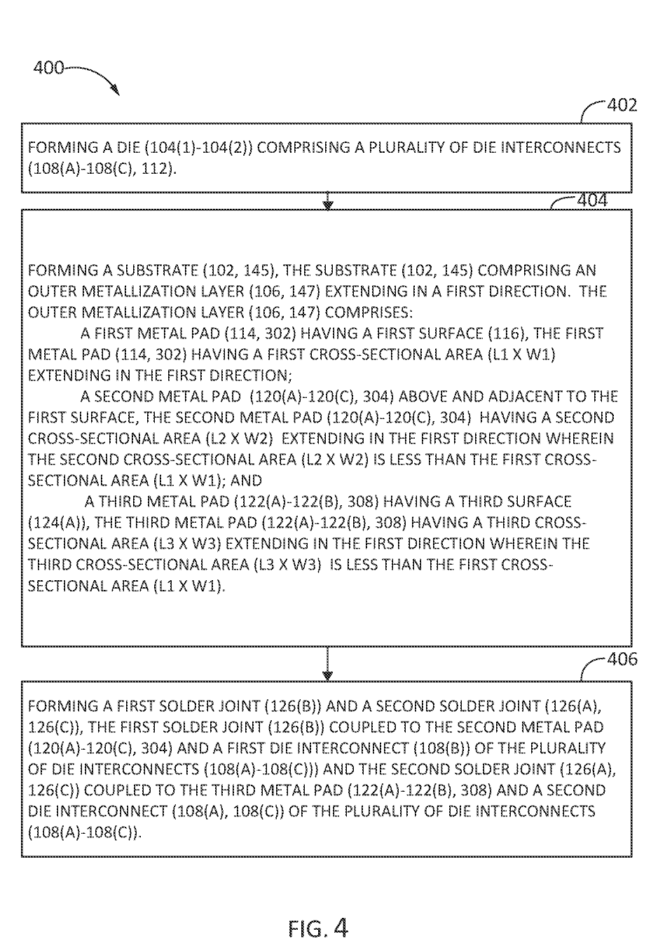

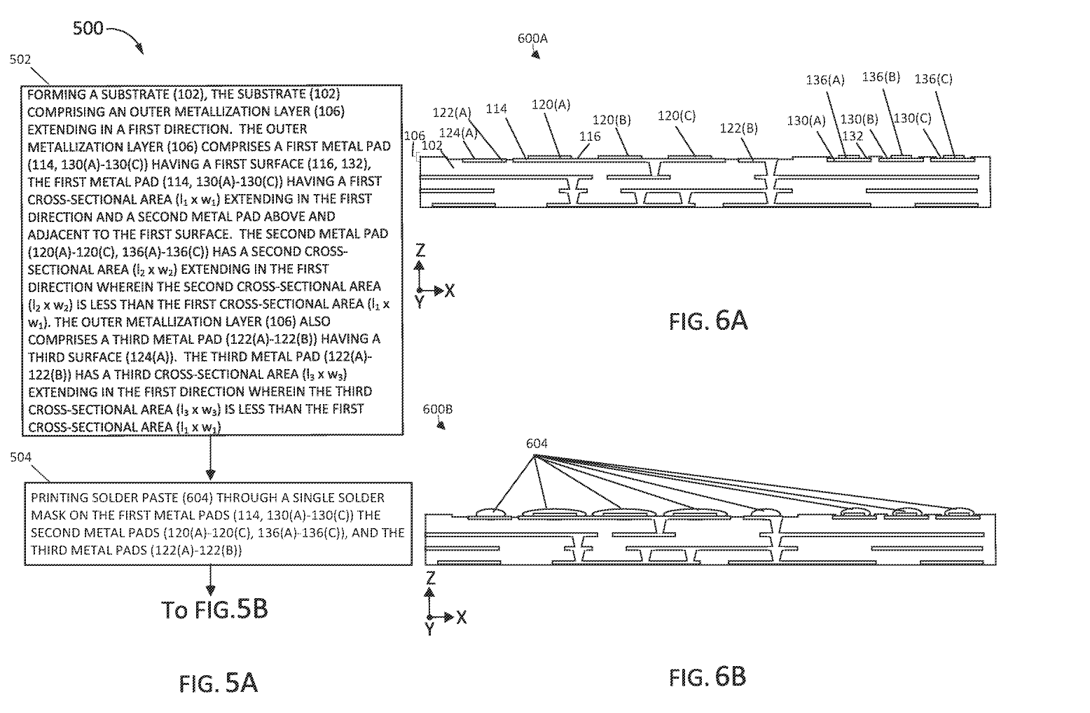

Other fabrication processes can also be employed fabricate an IC package such as the IC package described in FIGS. 1A-1B, 2, and FIGS. 3A-3B, wherein the IC package includes a substrate employing an added metal pad(s) to a metal interconnect(s) to reduce air voids in a solder joint, including, but not limited to, the solder joints in FIGS. 1A-1B. In this regard, FIGS. 5A-5B is a flowchart illustrating another exemplary fabrication process 500 of fabricating an IC package utilizing a substrate such as the IC package described in FIGS. 1A-1B, 2, and FIGS. 3A-3B, wherein the substrate employs a reduced area, added metal pad(s) to a metal interconnect(s) to reduce air voids in a solder joint(s), including, but not limited to, the solder joints in FIGS. 1A-1B. FIGS. 6A-6D are exemplary fabrication stages during fabrication of the IC package according to the fabrication process in FIGS. 5A-5B. The fabrication process 500 as shown in the fabrication stages 600A-600D in FIGS. 6A-6D are in reference to the IC package 100 in FIG. 1A, and thus will be discussed with reference to the IC package 100 in FIG. 1A.

In this regard, as shown in fabrication stage 600A in FIG. 6A, an exemplary step in the fabrication process 500 is forming a substrate 102, the substrate 102 comprising an outer metallization layer 106 extending in a first direction. The outer metallization layer 106 comprises a first metal pad 114, 130(A)-130(C) having a first surface 116, 132, the first metal pad 114, 130(A)-130(C) having a first cross-sectional area, l₁ x w₁, extending in the first direction and a second metal pad 120(A)-120(C), 136(A)-136(C) above and adjacent to the first surface 116, 132. The second metal pad 120(A)-120(C), 136(A)-136(C) has a second cross-sectional area, l₂ x w₂, extending in the first direction, wherein the second cross-sectional area, l₂ x w₂, is less than the first cross-sectional area, l₁ x w₁. The outer metallization layer 106 also comprises a third metal pad 122(A)-122(B) having a third surface 124(A). The third metal pad 122(A)-122(B) has a third cross-sectional area, l₃ x w₃, extending in the first direction, wherein the third cross-sectional area, l₃ x w₃, is less than the first cross-sectional area, l₁ x w₁ (block 502 in FIG. 5A). As shown at fabrication stage 600B in FIG. 6B, a next step in the fabrication process 500 can include printing solder paste 604 through a single print screen stencil on the first metal pads 114, 130A-130C, the second metal pads 120(A)-120(C), 136(A)-136(C), and the third metal pads 122(A)-122(B) (block 504 in FIG. 5A). As shown at fabrication stage 600C in FIG. 6C, a next step in the fabrication process 500 can include aligning/placing dies 104(1), 104(2) onto the substrate 102 utilizing conventional surface mount technology (SMT) processes and reflowing the electronic device to form solder joints 126(A)-126(C), 138(A)-138(C) (block 506 in FIG. 5B). The second metal pads 120(A)-120(C), 136(A)-136(C) will occupy volume that otherwise would be consumed by solder paste in order to reduce, if not avoid, air voids in the solder joints. As shown at fabrication stage 600D in FIG. 6D, a next step in the fabrication process 500 can include applying over-molding processes and post-processing package processes to complete the assembly of the IC package 100 (block 508 in FIG. 5B).

Please note that micro metal pads may be applied to LGAs and flip chip style pads. Micro metal pads will displace volume which would otherwise be consumed by solder and will push out trapped gases to reduce, if not eliminate, air voids in a solder joint. The thickness of a single print screen stencil for applying solder paste is generally tailored to the smallest cross-sectional area of a metal pad in the outer metallization layer.

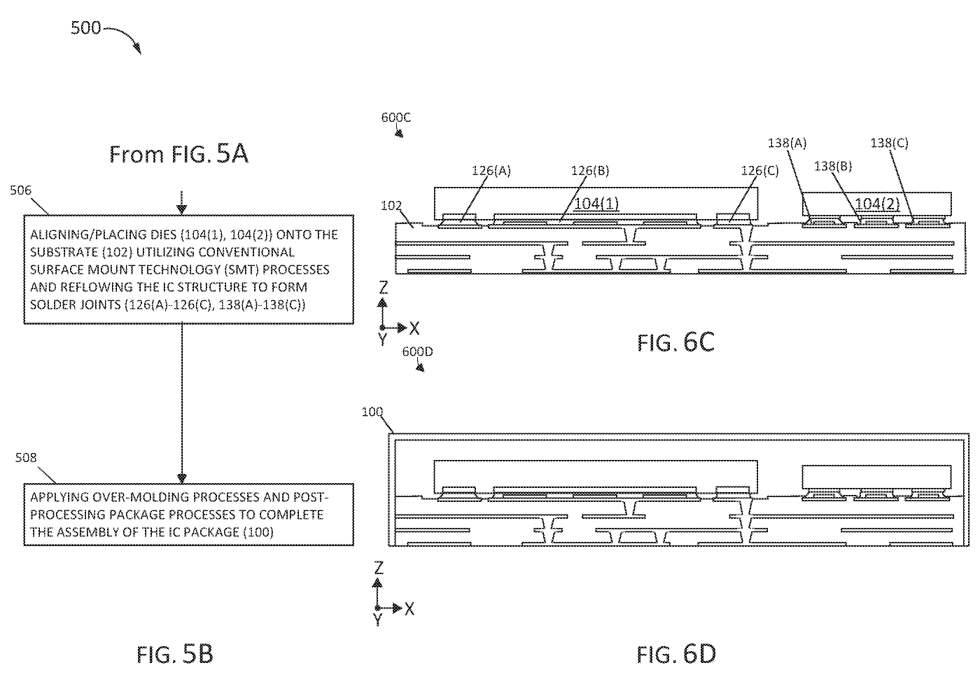

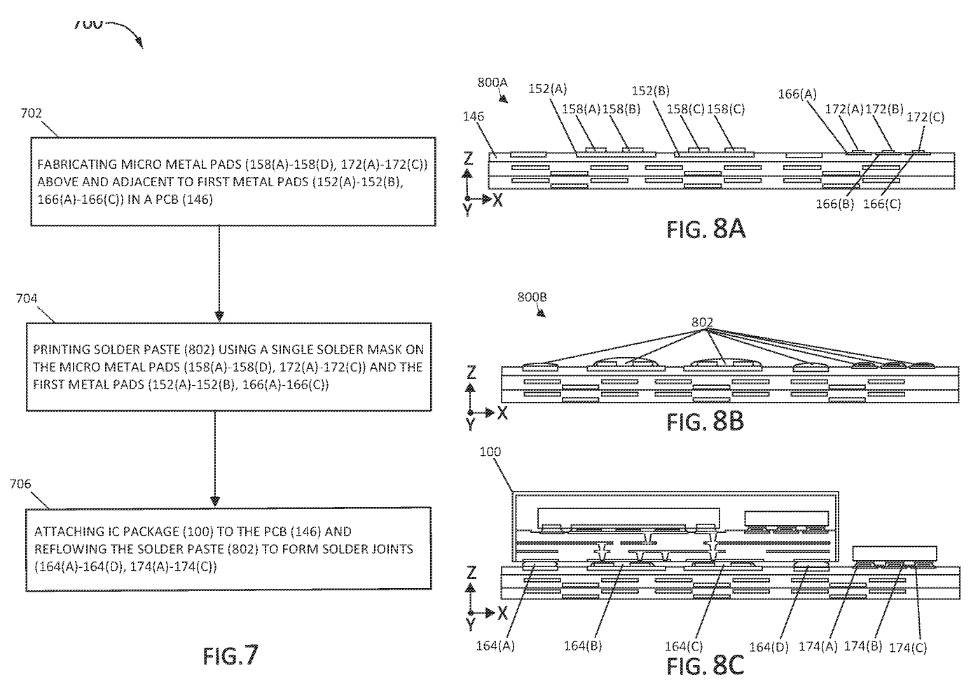

Micro metal pads may be deployed in an electronic device where IC packages are mounted on a PCB. In this regard, FIG. 7 is a flowchart illustrating an exemplary assembly process of assembling an electronic device such as the electronic device having a PCB in FIG. 1B and utilizing the IC package fabricated according to the fabrication process in FIGS. 5A-5B, wherein the PCB employs a reduced area, added metal pad(s) to a metal interconnect(s) to reduce air voids in a solder joint(s) including, but not limited to, the solder joints in FIGS. 1A-1B. FIGS. 8A-8C are exemplary assembly stages during assembly of the electronic device according to the assembly process in FIG. 7. FIGS. 7 and 8A-8C will be discussed in connection with electronic device 145.

As shown in fabrication stage 800A in FIG. 8A, an exemplary step in the fabrication process 700 is fabricating micro metal pads 158(A)-158(D), 172(A)-172(C) above and adjacent to first metal pads 152(A)-152(B), 166(A)-166(C) in a PCB 146 (block 702 in FIG. 7). As shown at fabrication stage 800B in FIG. 8B, a next step in the fabrication process 700 can include printing solder paste 802 using a single print screen stencil on the micro metal pads 158(A)-158(D), 172(A)-172(C) and the first metal pads 152(A)-152(B), 166(A)-166(C) (block 704 in FIG. 7). As shown at fabrication stage 800C in FIG. 8C, a next step in the fabrication process 700 can include attaching the IC package 100 to the PCB 146 and reflowing the solder paste 802 to form solder joints 164(A)-164(D), 174(A)-174(C) (block 706 in FIG. 7).

Electronic devices that include an IC package, wherein the IC package includes a substrate(s) employing an added metal pad(s) (micro metal pads) to a metal interconnect(s) to reduce, if not avoid, air voids in a solder joint, including, but not limited to, the IC package in FIG. 1A and the electronic device in FIG. 1B and according to the exemplary processes in FIGS. 4, 5A-5B and 7, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, and a multicopter.

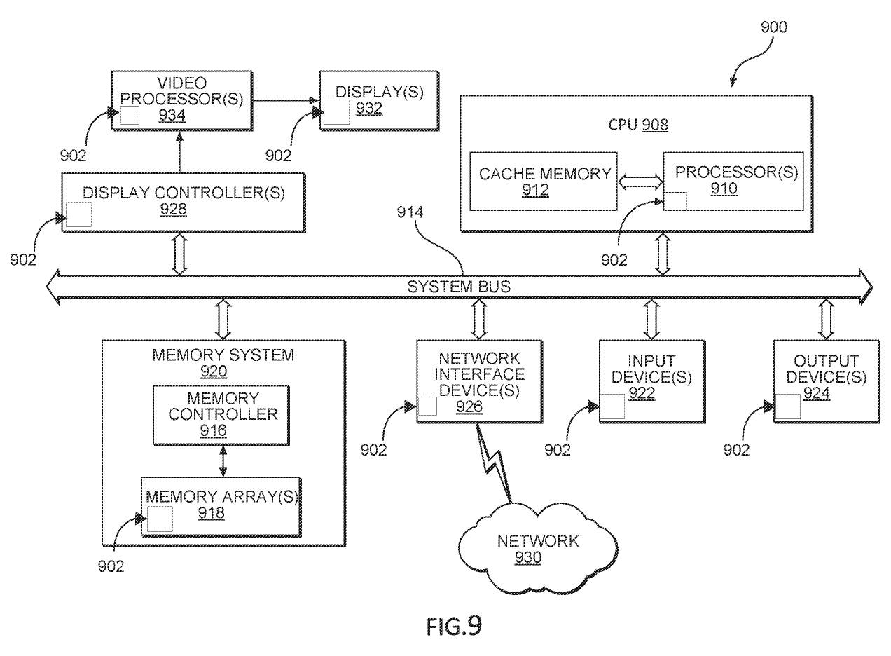

In this regard, FIG. 9 is a block diagram of an exemplary processor-based system 900 that can include components deployed in an electronic device, wherein the electronic device includes a substrate(s) employing a reduced area, added metal pad(s) to a metal interconnect(s) to reduce air voids in a solder joint, including, but not limited to, the solder joints in FIGS. 1A-1B and according to the exemplary fabrication processes in FIGS. 4 and 5A-5C, and according to any exemplary aspects disclosed herein. In this example, the processor-based system 900 may be formed as an IC package 902 such as the IC package 100 in FIG. 1A utilizing the substrate 102. The processor-based system 900 includes a central processing unit (CPU) 908 that includes one or more processors 910, which may also be referred to as CPU cores or processor cores. The CPU 908 may have cache memory 912 coupled to the processor(s) 910 for rapid access to temporarily stored data. The CPU 908 is coupled to a system bus 914 and can intercouple master and slave devices included in the processor-based system 900. As is well known, the CPU 908 communicates with these other devices by exchanging address, control, and data information over the system bus 914. For example, the CPU 908 can communicate bus transaction requests to a memory controller 916, as an example of a slave device. Although not illustrated in FIG. 9, multiple system buses 914 could be provided, wherein each system bus 914 constitutes a different fabric.

Other master and slave devices can be connected to the system bus 914. As illustrated in FIG. 9, these devices can include a memory system 920 that includes the memory controller 916 and a memory array(s) 918, one or more input devices 922, one or more output devices 924, one or more network interface devices 926, and one or more display controllers 928, as examples. Each of the memory system 920, the one or more input devices 922, the one or more output devices 924, the one or more network interface devices 926, and the one or more display controllers 928 can be provided in the same or different electronic devices. The input device(s) 922 can include any type of input device, including, but not limited to, input keys, switches, voice processors, etc. The output device(s) 924 can include any type of output device, including, but not limited to, audio, video, other visual indicators, etc. The network interface device(s) 926 can be any device configured to allow exchange of data to and from a network 930. The network 930 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 926 can be configured to support any type of communications protocol desired.

The CPU 908 may also be configured to access the display controller(s) 928 over the system bus 914 to control information sent to one or more displays 932. The display controller(s) 928 sends information to the display(s) 932 to be displayed via one or more video processor(s) 934, which process the information to be displayed into a format suitable for the display(s) 932. The display controller(s) 928 and video processor(s) 934 can be included as ICs in the same or different electronic devices, and in the same or different electronic devices containing the CPU 908, as an example. The display(s) 932 can include any type of display, including, but not limited to, a cathode ray tube (CRT), a liquid crystal display (LCD), a plasma display, a light emitting diode (LED) display, etc.

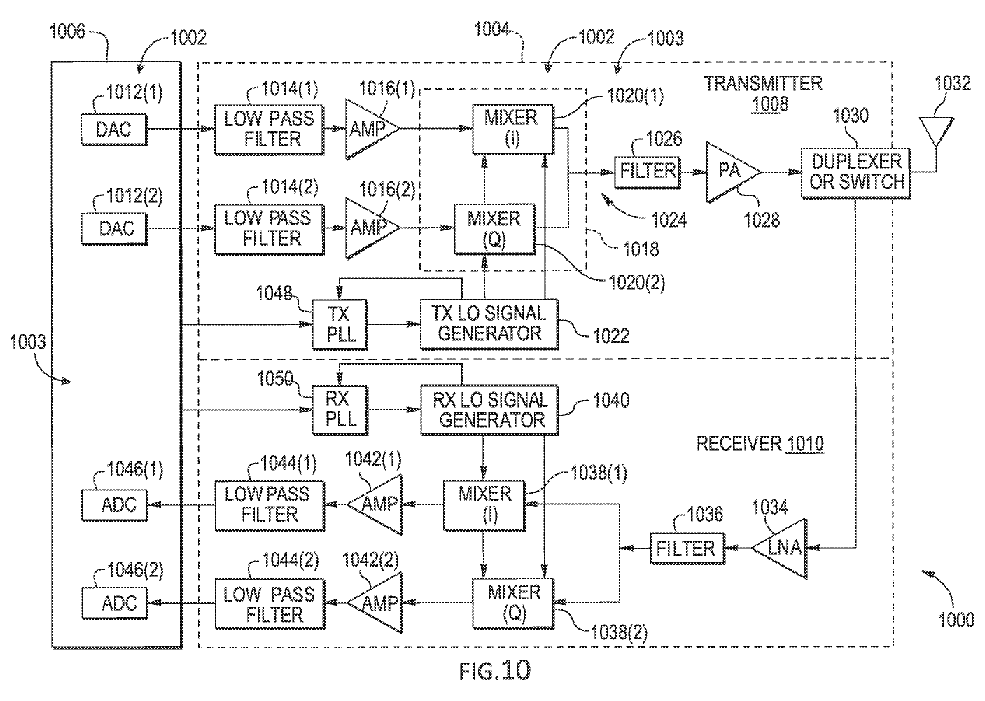

FIG. 10 is a block diagram of an exemplary wireless communications device 1000 that includes radio-frequency (RF) components formed from one or more electronic devices 1002, wherein any of the electronic devices 1002 includes an IC package 1003, wherein the IC package 1003 includes a substrate(s) employing a reduced area, added metal pad(s) to a metal interconnect(s) to reduce air voids in solder joint(s), including, but not limited to, the solder joints in FIGS. 1A-1B and according to the exemplary fabrication processes in FIGS. 4 and 5A-5C, and according to any exemplary aspects disclosed herein. The wireless communications device 1000 may include or be provided in any of the above-referenced devices, as examples. As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and frequency bands. All or a portion of the transceiver 1004 may be implemented on one or more analog ICs, RF ICs (RFICs), mixed-signal ICs, etc.

The transmitter 1008 or the receiver 1010 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 1010. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into the I and Q analog output signals (e.g., I and Q output currents) for further processing.

Within the transmitter 1008, lowpass filters 1014(1), 1014(2) filter the I and Q analog output signals, respectively, to remove undesired signals caused by the prior digital-to-analog conversion. Amplifiers (AMPs) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals through mixers 1020(1), 1020(2) from a TX LO signal generator 1022 to provide an upconverted signal 1024. A filter 1026 filters the upconverted signal 1024 to remove undesired signals caused by the frequency up-conversion as well as noise in a receive frequency band. A power amplifier (PA) 1028 amplifies the upconverted signal 1024 from the filter 1026 to obtain the desired output power level and provides a transmit RF signal. The transmit RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Down-conversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by AMPs 1042(1), 1042(2) and further filtered by lowpass filters 1044(1), 1044(2) to obtain I and Q analog input signals, which are provided to the data processor 1006. In this example, the data processor 1006 includes analog-to-digital converters (ADCs) 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency up-conversion, while the RX LO signal generator 1040 generates the I and Q RX LO signals used for frequency down-conversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

Those of skill in the art will further appreciate that the various illustrative logical blocks, modules, circuits, and algorithms described in connection with the aspects disclosed herein may be implemented as electronic hardware, instructions stored in memory or in another computer readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. An electronic device, comprising:

an integrated circuit (IC) package, comprising:

a die comprising a plurality of die interconnects; and

a substrate comprising an outer metallization layer extending in a first direction, the outer metallization layer comprising:

a first metal pad having a first surface, the first metal pad having a first cross-sectional area extending in the first direction;

a second metal pad above and adjacent to the first surface, the second metal pad having a second cross-sectional area extending in the first direction, the second cross-sectional area is less than the first cross-sectional area; and

a third metal pad having a third surface, the third metal pad having a third cross-sectional area extending in the first direction, the third cross-sectional area is less than the first cross-sectional area;

a first solder joint coupled to the second metal pad and a first die interconnect of the plurality of die interconnects; and

a second solder joint coupled to the third metal pad and a second die interconnect of the plurality of die interconnects.

2. The electronic device of clause 1, wherein the IC package further comprises:

a plurality of second metal pads including the second metal pad coupled to the first metal pad.

3. The electronic device of clause 2, wherein the plurality of second metal pads are distributed equally in the first direction within a perimeter of the first metal pad.

4. The electronic device of any of clauses 1-3, wherein the IC package further comprises:

a plurality of second solder joints; and

a plurality of third metal pads including the third metal pad, each of the plurality of third metal pads coupled to each of the plurality of second solder joints.

5. The electronic device of clause 4, wherein the plurality of third metal pads are distributed around a perimeter of the first metal pad.

6. The electronic device of clause 4 or 5, wherein the IC package further comprises:

a plurality of fourth pads, each of the plurality of fourth pads adjacent in a second direction to each of the plurality of third metal pads, each of the plurality of fourth pads having a fourth cross-sectional area extending in the first direction, the fourth cross-sectional area being less than the second cross-sectional area.

7. The electronic device of any of clauses 1-6, wherein the second metal pad is electrically coupled to a ground plane in the die and the third metal pad is electrically coupled to a signal pad in the die.

8. The electronic device of clause 7, wherein the ground plane is adjacent to a bottom surface of the die and is a primary thermal dissipation path of heat through the bottom surface.

9. The electronic device of any of clauses 1-8, wherein the outer metallization layer further comprises:

a fourth metal pad above and adjacent to the third surface, the fourth metal pad having a fourth cross-sectional area extending in the first direction, the fourth cross-sectional area is less than the third cross-sectional area.

10. The electronic device of any of clauses 2-9, wherein a total cross-sectional area of the plurality of second metal pads is at least 30 percent of the first cross-sectional area of the first metal pad.

11. The electronic device of any of clauses 1-10, wherein the substrate is a printed circuit board.

12. The electronic device of any of clauses 1-11, wherein the first solder joint and the second solder joint are fabricated with a single solder paste stencil.

13. The electronic device of any of clauses 1-12 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

14. A method for fabricating an electronic device, comprising:

forming a die comprising a plurality of die interconnects;

forming a substrate, the substrate comprising an outer metallization layer extending in a first direction, the outer metallization layer comprising:

a first metal pad having a first surface, the first metal pad having a first cross-sectional area extending in the first direction;

a second metal pad above and adjacent to the first surface, the second metal pad having a second cross-sectional area extending in the first direction, the second cross-sectional area is less than the first cross-sectional area; and

a third metal pad having a third surface, the third metal pad having a third cross-sectional area extending in the first direction, the third cross-sectional area is less than the first cross-sectional area; and

forming a first solder joint and a second solder joint, the first solder joint coupled to the second metal pad and a first die interconnect of the plurality of die interconnects and the second solder joint coupled to the third metal pad and a second die interconnect of the plurality of die interconnects.

15. The method of clause 14, wherein forming the first solder joint and the second solder joint comprises applying a solder paste through a single print screen stencil to form both the first solder joint and the second solder joint.

16. The method of clause 15, wherein forming the first solder joint and the second solder joint further comprises reflowing the solder paste.

17. The method of any of clauses 14-16, wherein forming the substrate further comprises forming a plurality of second metal pads including the second metal pad coupled to the first metal pad.

18. The method of clause 17, wherein the plurality of second metal pads are distributed equally in the first direction within a perimeter of the first metal pad.

19. The method of any of clauses 14-18, wherein the outer metallization layer further comprises:

a fourth metal pad above and adjacent to the third surface, the fourth metal pad having a fourth cross-sectional area extending in the first direction, the fourth cross-sectional area is less than the third cross-sectional area.

20. The method of any of clauses 17-19, wherein a total cross-sectional area of the plurality of second metal pads is at least 30 percent of the first cross-sectional area of the first metal pad.

What is claimed is:

1. An electronic device, comprising:
an integrated circuit (IC) package, comprising:
a die comprising a plurality of die interconnects; and
a substrate comprising an outer metallization layer extending in a first direction, the outer metallization layer comprising:
a first metal pad having a first surface, the first metal pad having a first cross-sectional area extending in the first direction;
a second metal pad above and adjacent to the first surface, the second metal pad having a second cross-sectional area extending in the first direction, the second cross-sectional area is less than the first cross-sectional area; and
a third metal pad having a third surface, the third metal pad having a third cross-sectional area extending in the first direction, the third cross-sectional area is less than the first cross-sectional area;
a first solder joint coupled to the second metal pad and a first die interconnect of the plurality of die interconnects; and
a second solder joint coupled to the third metal pad and a second die interconnect of the plurality of die interconnects.

2. The electronic device of claim 1, wherein the IC package further comprises:
a plurality of second metal pads including the second metal pad coupled to the first metal pad.

3. The electronic device of claim 2, wherein the plurality of second metal pads are distributed equally in the first direction within a perimeter of the first metal pad.

4. The electronic device of claim 1, wherein the IC package further comprises:
a plurality of second solder joints; and
a plurality of third metal pads including the third metal pad, each of the plurality of third metal pads coupled to each of the plurality of second solder joints.

5. The electronic device of claim 4, wherein the plurality of third metal pads are distributed around a perimeter of the first metal pad.

6. The electronic device of claim 4, wherein the IC package further comprises:
a plurality of fourth pads, each of the plurality of fourth pads adjacent in a second direction to each of the plurality of third metal pads, each of the plurality of fourth pads having a fourth cross-sectional area extending in the first direction, the fourth cross-sectional area being less than the second cross-sectional area.

7. The electronic device of claim 1, wherein the second metal pad is electrically coupled to a ground plane in the die and the third metal pad is electrically coupled to a signal pad in the die.

8. The electronic device of claim 7, wherein the ground plane is adjacent to a bottom surface of the die and is a primary thermal dissipation path of heat through the bottom surface.

9. The electronic device of claim 1, wherein the outer metallization layer further comprises:
a fourth metal pad above and adjacent to the third surface, the fourth metal pad having a fourth cross-sectional area extending in the first direction, the fourth cross-sectional area is less than the third cross-sectional area.

10. The electronic device of claim 2, wherein a total cross-sectional area of the plurality of second metal pads is at least 30 percent of the first cross-sectional area of the first metal pad.

11. The electronic device of claim 1, wherein the substrate is a printed circuit board.

12. The electronic device of claim 1, wherein the first solder joint and the second solder joint are fabricated with a single solder paste stencil.

13. The electronic device of claim 1, integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

14. A method for fabricating an electronic device, comprising:
forming a die comprising a plurality of die interconnects;
forming a substrate, the substrate comprising an outer metallization layer extending in a first direction, the outer metallization layer comprising:
a first metal pad having a first surface, the first metal pad having a first cross-sectional area extending in the first direction;
a second metal pad above and adjacent to the first surface, the second metal pad having a second cross-sectional area extending in the first direction, the second cross-sectional area is less than the first cross-sectional area; and
a third metal pad having a third surface, the third metal pad having a third cross-sectional area extending in the first direction, the third cross-sectional area is less than the first cross-sectional area; and
forming a first solder joint and a second solder joint, the first solder joint coupled to the second metal pad and a first die interconnect of the plurality of die interconnects and the second solder joint coupled to the third metal pad and a second die interconnect of the plurality of die interconnects.

15. The method of claim 14, wherein forming the first solder joint and the second solder joint comprises applying a solder paste through a single print screen stencil to form both the first solder joint and the second solder joint.

16. The method of claim 15, wherein forming the first solder joint and the second solder joint further comprises reflowing the solder paste.

17. The method of claim 14, wherein forming the substrate further comprises forming a plurality of second metal pads including the second metal pad coupled to the first metal pad.

18. The method of claim 17, wherein the plurality of second metal pads are distributed equally in the first direction within a perimeter of the first metal pad.

19. The method of claim 14, wherein the outer metallization layer further comprises:
a fourth metal pad above and adjacent to the third surface, the fourth metal pad having a fourth cross-sectional area extending in the first direction, the fourth cross-sectional area is less than the third cross-sectional area.

20. The method of claim 17, wherein a total cross-sectional area of the plurality of second metal pads is at least 30 percent of the first cross-sectional area of the first metal pad.
